(19) United States
(12) Patent Application Publication
(10) Pub. No.: US 2003/0073280 A1
(43) Pub. Date: Apr. 17, 2003

(54) Semiconductor device and fabrication process therefor

(75) Inventors: Heiji Kobayashi, Hyogo (JP); Shinya Nakatani, Hyogo (JP)

Correspondence Address: McDermott, Will & Emery, 600 13th Street, N.W., Washington, DC, 20005-3096, US

(73) Assignee: MITSUBISHI DENKI KABUSHIKI KAISHA, Tokyo (JP)

(21) Appl. No.: 10/293,304

(22) Filed: Nov. 14, 2002

Related U.S. Application Data
(62) Division of application No. 09/909,783, filed on Jul. 23, 2001.

(30) Foreign Application Priority Data
Jan. 24, 2001 (JP) 2001-015329 (P)

(51) Int. Cl. H01L 31/119; H01L 29/76; H01L 21/8242; H01L 27/108; H01L 29/94

(52) U.S. Cl. 438/239; 257/296

(57) ABSTRACT

A semiconductor device with a high reliability is provided. A DRAM includes a source and drain region, an interlayer insulating film having a contact hole which reaches to the surface of the source and drain region and a bit line which is covered by the interlayer insulating film. The contact hole is defined by the sidewalls of the interlayer insulating film. The DRAM includes a silicon nitride film which is formed on the sidewalls and a storage node which fills in the contact hole so as to be electrically connected to the source and drain region.

### BACKGROUND OF THE INVENTION

1. Field of the Invention

The present invention relates to a semiconductor device and a fabrication process therefor, in particular, to a dynamic random access memory (DRAM) and a process for the same.

2. Description of the Background Art

A dynamic random access memory is known as a semiconductor device wherein a random input and output of memory information is possible. FIG. 15 is a plan view of a DRAM according to a prior art. Referring to FIG. 15, the conventional DRAM 100 includes a gate electrode 10 as a word line, bit lines 110 and 120 formed above the gate electrode 10 and a storage node 140 formed between the bit lines 110 and 120.

The gate electrode 10 is formed so as to extend in a predetermined direction above a silicon substrate. The bit lines 110 and 120 extend in the direction approximately perpendicular to the direction in which the gate electrode 10 extends. A contact part 111, which protrudes in the direction that the gate electrode 10 extends, is formed in the bit line 110. A contact hole 20h which reaches to the silicon substrate is created in the contact part 111.

The storage node 140 is formed between the bit lines 110 and 120 and above the bit lines 110 and 120. The storage node 140 is electrically connected with the silicon substrate through the contact hole 30h. The storage node 140 extends in the direction approximately perpendicular to the direction in which the bit lines 110 and 120 extend.

FIG. 16 is a view showing a cross section along the line XVI-XVI in FIG. 15. Referring to FIG. 16, a source and drain region 3, formed of an impurity region, is formed in a silicon substrate 1. An interlayer insulating film 20 is formed on the silicon substrate 1. Bit lines 110 and 120 are formed on the interlayer insulating film 20. An interlayer insulating film 30 is formed so as to cover the bit lines 110 and 120. A contact hole 30h is created in the interlayer insulating films 30 and 20 so as to reach to the source and drain region 3. The contact hole 30h is defined by the sidewalls 31 of the interlayer insulating films 20 and 30.

A capacitor 170 is formed so as to be electrically connected to the source and drain region 3. The capacitor 170 is formed of a storage node 140 which makes contact with the source and drain region 3, a dielectric film 150 formed on the storage node 140 and a cell plate 160 formed on the dielectric film 150. The storage node 140 is formed on the interlayer insulating film 30 so as to fill in the contact hole 30h. The dielectric film 150 is formed so as to cover the storage node 140 and the interlayer insulating film 30. The dielectric film 150 is formed of a silicon nitride film. The cell plate 160 is formed so as to cover the dielectric film 150.

FIG. 17 is a view showing a cross section along the line XVII-XVII in FIG. 15. Referring to FIG. 17, the DRAM 100 is formed of a field effect transistor 9 and a capacitor 170 connected to the field effect transistor 9.

The field effect transistor 9 is formed of a gate electrode 10 which is formed above the silicon substrate 1 via a gate oxide film 4 and source and drain regions 2 and 3 formed in the silicon substrate 1 on both sides of gate electrode 10.

An interlayer insulating film 20 made of a silicon oxide film is formed on the surface of the silicon substrate 1. A contact hole 20h is created in the interlayer insulating film 20 so as to reach to the source and drain region 2. A bit line 110 is filled into the contact hole 20h.

An interlayer insulating film 30 made of a silicon oxide film is formed so as to cover the interlayer insulating film 20. A contact hole 30h is created in the interlayer insulating film 30 so as to reach to the source and drain region 3. The contact hole 30h is defined by the sidewalls 31 of the interlayer insulating films 20 and 30.

A capacitor 170 is formed on the interlayer insulating film 30 so as to be electrically connected to the field effect transistor 9. The capacitor 170 is formed of a storage node 140, a dielectric film 150 provided on the storage node 140 and a cell plate 160 provided on the dielectric film 150.

In the following, a process for the conventional DRAM is described. FIGS. 21 to 24 are views for describing problems caused in the conventional process. First, referring to FIG. 18, a gate oxide film and a gate electrode (not shown in FIG. 18) are formed on the silicon substrate 1. A source and drain region 3 is formed by injecting impurity ions into the silicon substrate 1 by using the gate electrode as a mask. An interlayer insulating film 20 made of a silicon oxide film is formed on the silicon substrate 1. A polysilicon film 210 is formed on the interlayer insulating film 20 through CVD (chemical vapor deposition). A resist is applied to the polysilicon film 210 and a resist pattern 310 is formed by patterning this resist into a predetermined form.

Referring to FIG. 19, the polysilicon film 210 is etched by using the resist pattern 310 as a mask. Thereby, bit lines 110 and 120 are formed.

Referring to FIG. 20, an interlayer insulating film 30 is formed on the interlayer insulating film 20 so as to cover the bit lines 110 and 120. A resist is applied to the interlayer insulating film 30 and a resist pattern 311 is formed by patterning this resist into a predetermined form. A contact hole 30h is created so as to reach to the source and drain region 3 by etching the interlayer insulating films 30 and 20 by using the resist pattern 311 as a mask. The contact hole 30h is defined by the sidewalls 31 of the interlayer insulating films 20 and 30.

Referring to FIG. 16, a polysilicon film is formed so as to fill in the contact hole 30h and to cover the surface of the interlayer insulating film 30. By patterning this polysilicon film into a predetermined form a storage node 140 is formed. A silicon nitride film is formed through CVD on the interlayer insulating film 30 so as to cover the storage node 140. A doped polysilicon film is formed on the silicon nitride film through CVD. A resist pattern is formed on the doped polysilicon film and by patterning the doped polysilicon film and the silicon nitride film in accordance with this resist pattern a cell plate 160 and a dielectric film 150 are formed. Thereby, the DRAM 100 as shown in FIG. 16 is completed.

In recent years the miniaturization of DRAMs has progressed and, for example, the gate length of the gate electrode 10 has become 0.15 μm, or less, the width W₁ of the bit lines 110 and 120 has become 0.15 μm, or less, and the distance between the bit line 110 and the contact hole 30h has become 0.1 μm, or less.

In the following, problems caused by the progress of such a miniaturization are described referring to the drawings. FIG. 21 to 24 are the views for describing the problems caused in the conventional technology. Referring to FIG. 21, at the time of patterning the doped polysilicon film 210, a resist is applied to the doped polysilicon film 210 and this resist is patterned in accordance with a photolithographic process. At this time, there is the case where a part, which is originally not supposed to be exposed, is exposed so that a protruding part 311 occurs in the resist pattern 310. The protruding part 311 in the resist pattern 310 has a width W₂ which is smaller than the width W₁.

Referring to FIG. 22, the doped polysilicon film 210 is etched by using the resist pattern 310 as a mask. At this time, the doped polysilicon film 210 is removed as the etching progresses and at an initial stage of the etching, the doped polysilicon film beneath the protruding part 311 is not etched because of the existence of the protruding part 311. When the etching progress to a certain extent so that the protruding part 311 is etched and removed, the doped polysilicon film 210 beneath the protruding part 311 is also etched. Therefore, at the stage where the etching is finished a small amount of doped polysilicon film remains beneath the protruding part 311 so that this part becomes a protruding part 112 of the bit line 110. Here, the resist pattern 310 on the bit lines 110 and 120 is also etched so that the thickness thereof becomes lesser.

Referring to FIG. 23, the interlayer insulating film 30 is formed so as to cover the bit lines 110 and 120. The resist pattern 311 is formed on the interlayer insulating film 30 and the interlayer insulating films 30 and 20 are removed through etching in accordance with the resist pattern 311. Thereby, the contact hole 30h is created. Since the distance between the contact hole 30h and the bit line 110 is small, the protruding part 112 of the bit line 110 reaches to the contact hole 30h.

Referring to FIG. 24, a doped polysilicon film is formed on the interlayer insulating film 30 so as to fill in the contact hole 30h. A resist pattern is formed on the doped polysilicon film and by etching the doped polysilicon film in accordance with this resist pattern a storage node 140 is formed. A dielectric film 150 and a cell plate 160 are formed on the storage node 140 so as to complete the DRAM 100.

In such a DRAM 100, the protruding part 112 of the bit line 110 and the storage node 140 contact each other so as to create a defective product. Ordinarily, such a defect allows a leak current to flow between the bit line 110 and the storage node 140. An inspection is carried out which senses this leak current and such a DRAM 100 is determined to be a defective product.

Since the contact area is small between the storage node 140 and the protruding part 112 of the bit line 110, however, in many cases this leak current is small and, therefore, it is difficult to detect the leak current through testing. Thereby, there is the problem that the reliability of the semiconductor device is lowered.

Such a problem could occur not only in the case where a protruding part 311 occurs in the resist pattern 310 which causes the occurrence of the protruding part 112 as described above but also in the case where conductive dust becomes attached to the bit line 110 so as to form a protruding part of the bit line 110 or even in the case where a foreign object within the bit line 110 forms the protruding part 112.

### SUMMARY OF THE INVENTION

Therefore, this invention is provided to solve the above described problems and the purpose of the invention is to provide a semiconductor device with a high reliability.

A semiconductor device according to one aspect of this invention includes a first conductive layer, a first insulating layer having a hole which reaches to the surface of the first conductive layer and a second conductive layer which is covered by the first insulating layer. The hole is defined by the sidewalls of the first insulating layer. The semiconductor device further includes a second insulating layer formed on the sidewalls of the hole and a third conductive layer which fills into the hole so as to be electrically connected to the first conductive layer.

In a semiconductor device formed in this manner, since the second insulating layer is formed on the sidewalls of the hole, the second insulating film is interposed between the first conductive layer which is covered by the first insulating layer and the third conductive layer which fills into the hole. Therefore, since the first conductive layer and the third conductive layer do not directly make contact with each other, no leak current occurs between the first conductive layer and the third conductive layer so that a semiconductor device with a high reliability can be provided.

In addition, part of the surface of the second conductive layer is exposed through the first insulating layer to the hole and may be isolated from the third conductive layer by the second insulating layer. In this case, even though the second conductive layer has a protruding part and part of the surface thereof is exposed through the first insulating layer, no leak current occurs.

In addition, the hole preferably includes an extending part which extends in the direction approaching the second conductive layer. In this case, the diameter of the hole can be made large since the hole includes the extending part.

In addition, the first conductive layer is preferably one of a pair of source and drain regions which are formed in the semiconductor substrate so as to be spaced apart from each other, the second conductive layer is a bit line of the dynamic random access memory which is connected to the other one of the pair of source and drain regions and the third conductive layer is a storage node of the dynamic random access memory which is connected to one of the pair of source and drain regions. In this case, the occurrence of a leak current can be prevented between the bit line and the storage node so that a DRAM with a high reliability can be provided.

A semiconductor device according to another aspect of this invention includes a first conductive layer, a first insulating layer having a first hole which reaches to the surface of the first conductive layer and a second conductive layer which is covered by the first insulating layer. The first hole is defined by the sidewalls of the first insulating layer and a second hole is formed in the first insulating layer so as to connect to the first hole and to divide the second conductive layer. The semiconductor device further includes a third conductive layer which is isolated from the second conductive layer so as to be electrically insulated from the second conductive layer and which fills into the first hole so as to be electrically connected to the first conductive layer.

In the semiconductor device formed in this manner, since the second conductive layer is separated by the second hole, it becomes easy to determine that this second conductive layer is defective in the subsequent testing. As a result, by replacing this second conductive layer with another conductive layer, the reliability of the semiconductor device is improved.

In addition, the first conductive layer is preferably one of a pair of source and drain regions which are formed in the semiconductor substrate so as to be spaced apart from each other, the second conductive layer is a bit line of the dynamic random access memory which is connected to the other one of the pair of source and drain regions and the third conductive layer is a storage node of the dynamic random access memory which is connected to one of the pair of source and drain regions.

A fabrication process for a semiconductor device according to this invention includes the step of forming a first conductive layer in a semiconductor substrate, the step of forming a second conductive layer on the semiconductor substrate, the step of forming a first insulating layer so as to cover the second conductive layer, the step of creating a hole, which reaches to the surface of the first conductive layer and which has sidewalls, in the first insulating layer, the step of forming a second insulating layer on the sidewalls of the hole and the step of forming a third conductive layer which is electrically connected to the first conductive layer and which fills into the hole on the second insulating layer.

In the fabrication process for a semiconductor device including such steps, the second insulating layer is formed on the sidewalls of the hole and the third conductive layer is formed on this second insulating layer. Therefore, since the second insulating layer interposes between the second conductive layer and the third conductive layer, the second conductive layer and the third conductive layer do not directly make contact with each other so that the occurrence of a leak current can be prevented. As a result, the reliability of the semiconductor device is improved.

In addition, the step of forming a hole in the first insulating layer preferably includes the creation of a hole which exposes part of the surface of the second conductive layer and the step of forming a second insulating layer on the sidewalls of the hole includes the formation of the second insulating layer which makes contact with the exposed second conductive layer.

In addition, preferably the process for a semiconductor device further includes the step of removing part of the surface of the second conductive layer which appears in the hole. In this case, since part of the surface of the second conductive layer is removed, the second conductive layer will not protrude into the hole. Therefore, the desired diameter of the hole can be maintained.

In addition, the step of removing part of the surface of the second conductive layer preferably includes the etching of the second conductive layer under the condition where the etching rate of the second conductive layer is greater than the etching rates of the first conductive layer as well as of the first and the second insulating layers.

In addition, the step of removing part of the surface of the second conductive layer preferably includes the wet etching of the second conductive layer.

A fabrication process for a semiconductor device according to another aspect of this invention includes the step of forming a first conductive layer in a semiconductor substrate, the step of forming a second conductive layer on the semiconductor substrate, the step of forming a first insulating layer so as to cover the second conductive layer, the step of creating, in the first insulating layer, a first hole which reaches to the surface of the first conductive layer and exposes part of the surface of the second conductive layer and which has sidewalls, the step of creating, in the first insulating layer, a second hole which is connected to the first hole and which separates the second conductive layer by removing a part of the second conductive layer which appears in the first hole and the step of forming a third conductive layer which is isolated from the second conductive layer so as to be electrically insulated from the second conductive layer and which fills into the hole so as to be electrically connected to the first conductive layer.

In the fabrication process for a semiconductor device including such steps, the second hole is created so as to separate the second conductive layer. Therefore, it becomes easy in the subsequent testing to determine that this semiconductor device is a defective product. As a result, by replacing this semiconductor device with another semiconductor device, the reliability of the semiconductor device is improved.

In addition, the removal of a part of the second conductive layer preferably includes the etching of the second conductive layer under the condition where the etching rate of the second conductive layer is greater than the etching rates of the first conductive layer and of the first insulating layer.

In addition, the removal of a part of the second conductive layer preferably includes the wet etching of the second conductive layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a DRAM according to a first embodiment of this invention;

FIG. 2 is a view showing a cross section along the line II-II in FIG. 1;

FIG. 3 is a view showing a cross section along the line III-III in FIG. 1;

FIGS. 4 to 9 are cross section views showing the first to sixth steps of a fabrication process for the DRAM as shown in FIG. 2;

FIG. 10 is a plan view of a DRAM according to a second embodiment of this invention;

FIG. 11 is a view showing a cross section along the line XI-XI in FIG. 10;

FIG. 12 is a view showing a cross section along the line XII-XII in FIG. 10;

FIGS. 13 and 14 are cross section views showing the first and the second steps of a fabrication process for the DRAM as shown in FIG. 11;

FIG. 15 is a plan view of a DRAM according to a prior art;

FIG. 16 is a view showing a cross section along the line XVI-XVI in FIG. 15;

FIG. 17 is a view showing a cross section along the line XVII-XVII in FIG. 15;

FIGS. 18 to 20 are cross section views showing the first to the third steps of a fabrication process for the DRAM as shown in FIG. 16; and

FIGS. 21 to 24 are views for describing problems caused in the conventional process.

### DESCRIPTION OF THE PREFERRED EMBODIMENTS

In the following, embodiments of the present invention are described referring to FIGS.

### First Embodiment

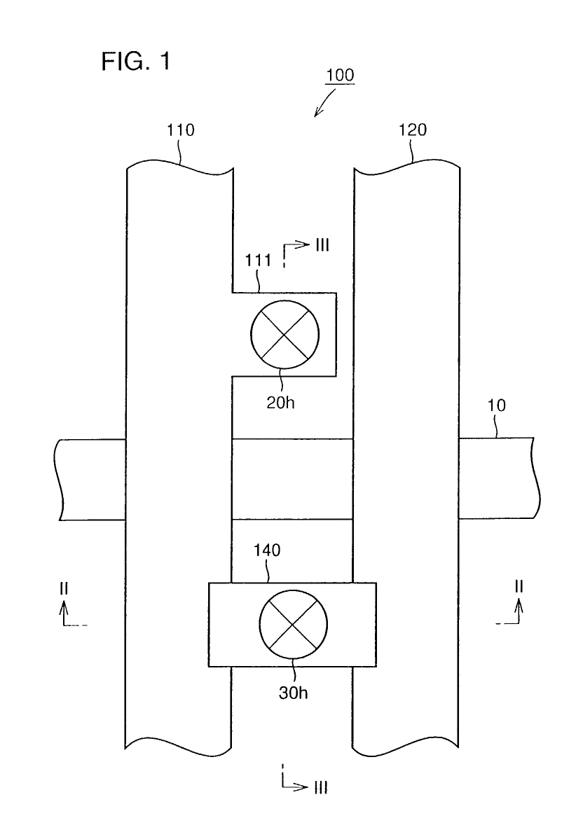

Referring to FIG. 1, a DRAM 1, as a semiconductor device, according to the first embodiment of this invention includes a gate electrode 10, as a word line, formed on a silicon substrate, bit lines 110 and 120 formed above the gate electrode 10 and a storage node 140 formed between the bit lines 110 and 120.

The gate electrode 10 is formed so as to extend in a predetermined direction on the silicon substrate. An interlayer insulating film (not shown in FIG. 1) is formed so as to cover the gate electrode 10 and bit lines 110 and 120 are formed on the interlayer insulating film. The bit lines 110 and 120 extend in the direction approximately perpendicular to the direction in which the gate electrode 10 extends. A contact part 111, which protrudes in the direction that the gate electrode 10 extends, is formed in the bit line 110. Here, instead of the formation of the contact part 111 in a protruding form, a part making contact with the silicon substrate may be formed by making the bit line 110 in a winding form. A contact hole 20h which reaches to the silicon substrate is created in the contact part 111.

The storage node 140 is formed between the bit lines 110 and 120 and above the bit lines 110 and 120 so as to be insulated from the bit lines 110 and 120. The storage node 140 is electrically connected to the silicon substrate through a contact hole 30h. The storage node 140 extends in the direction approximately perpendicular to the direction in which the bit lines 110 and 120 extend.

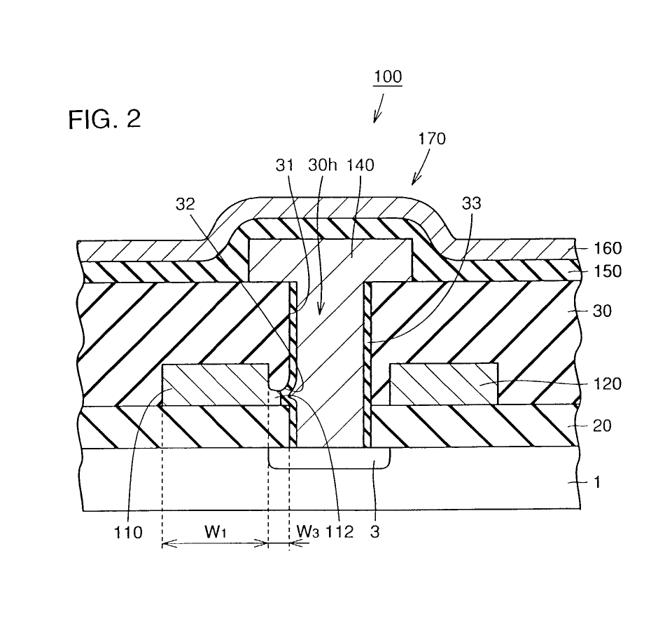

Referring to FIG. 2, a DRAM 100 as a semiconductor device according to this invention includes a source and drain region 3 as the first conductive layer, interlayer insulating films 20 and 30 as the first insulating layer having the contact hole 30h which reaches to the surface of the source and drain region 3 and bit lines 110 and 120 as the second conductive layer covered by the interlayer insulating films 20 and 30. The contact hole 30h is defined by the sidewalls 31 of the interlayer insulating films 20 and 30. The DRAM 100 includes a silicon nitride film 33 as the second insulating layer formed on the sidewalls 31 of the contact hole 30h and the storage node 140 as the third conductive layer that fills into the contact hole 30h so as to be electrically connected to the source and drain region 3.

The source and drain region 3, formed of an impurity region, is formed in the silicon substrate 1. The interlayer insulating film 20 is formed on the silicon substrate 1 so as to cover the source and drain region 3. Bit lines 110 and 120 are formed on the interlayer insulating film 20. The bit lines 110 and 120 extend from the front to the rear of the paper surface. The interlayer insulating film 30 is formed so as to cover the bit lines 110 and 120. The contact hole 30h which reaches to the source and drain region 3 is formed in the interlayer insulating films 30 and 20. The contact hole 30h is defined by the sidewalls 31 of the interlayer insulating films 20 and 30.

A capacitor 170 for storing information is formed so as to be electrically connected to the source and drain region 3. The capacitor 170 is formed of the storage node 140 which makes contact with the source and drain region 3, a dielectric film 150 which is formed on the storage node 140 and a cell plate 160 which is formed on the dielectric film 150. The storage node 140 is formed on the interlayer insulating film 30 so as to fill into the contact hole 30h. The dielectric film 150 in a thin film form is formed so as to cover the storage node 140 and the interlayer insulating film 30. The dielectric film 150 is formed of a silicon nitride film. A cell plate 160 is formed so as to cover the dielectric film 150.

A protruding part 112 which protrudes in the lateral direction is formed in the bit line 110 so that a part of the surface of the protruding part 112 is exposed from the interlayer insulating films 20 and 30 through the contact hole 30h. Part of the surface of the protruding part 112 of bit line 110 is separated from the storage node 140 by the silicon nitride film 33. In addition, the contact hole 30h includes an extending part 32 which extends in the direction approaching the bit line 110.

The width W₁ of the bit line 110 is 0.15 μm or less and the distance W₃ between the bit line 110 and the sidewall 31 of the contact hole 30h is 0.10 μm or less.

The silicon nitride film 33, as an insulating film forming a frame, is formed on the sidewall 31 which defines the contact hole 30h. The silicon nitride film 33 interposes between the protruding part 112 of the bit line 110 and the storage node 140 so as to electrically insulate these from each other. In the silicon nitride film 33, part of the silicon nitride film 33 on the left side in FIG. 2 is formed along the extending part 32, wherein a lateral hole is created, and directly makes contact with the protruding part 112 of the bit line 110. Thereby, silicon nitride film 33 has a form so as to fill into the extending part 32. The contact hole 30h is created between the adjoining bit lines 110 and 120.

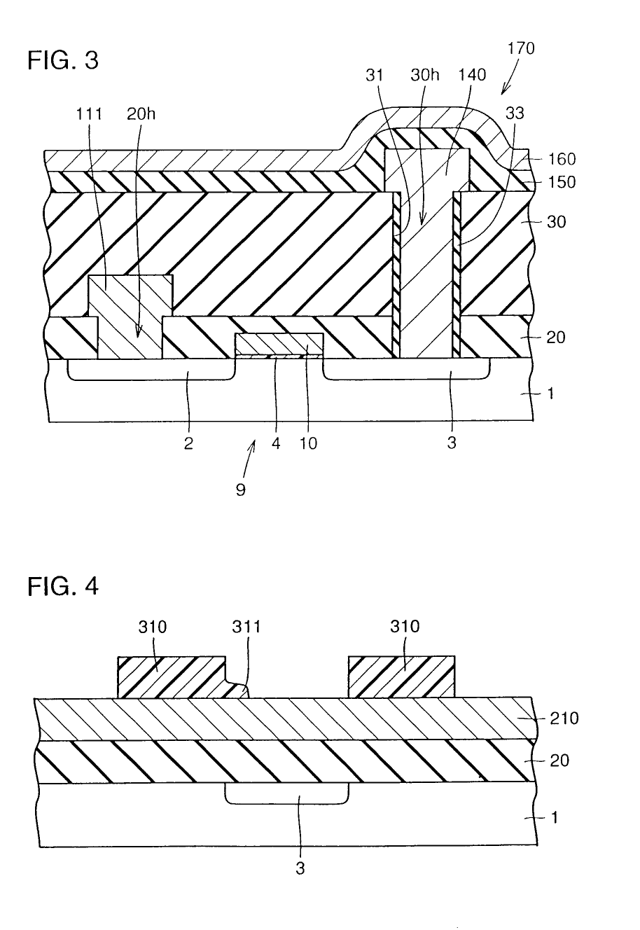

Referring to FIG. 3, the DRAM 100 is formed of the field effect transistor 9 and the capacitor 170 connected to the field effect transistor 9.

The field effect transistor 9 is formed of the gate electrode 10, which is formed above the silicon substrate 1 with the interposition of a gate oxide film 4, and the source and drain regions 2 and 3, which are formed in the silicon substrate 1 on both sides of the gate electrode 10.

The interlayer insulating film 20 made of a silicon oxide film is formed on the surface of the silicon substrate 1. The contact hole 20h, which reaches to the source and drain region 2, is formed in the interlayer insulating film 20. The bit line 110 is filled into the contact hole 20h.

The interlayer insulating film 30 made of a silicon oxide film is formed so as to cover the interlayer insulating film 20. The contact hole 30h, which reaches to the source and drain region 3, is formed in the interlayer insulating film 30. The contact hole 30h is defined by the sidewalls 31 of the interlayer insulating films 20 and 30.

The capacitor 170 is formed on the interlayer insulating film 30 so as to be electrically connected to the field effect transistor 9. The capacitor 170 is formed of the storage node 140, the dielectric film 150 which is provided on the storage node 140 and the cell plate 160 which is provided on the dielectric film 150.

The silicon nitride film 33 is formed so as to directly make contact with the sidewalls 31 which define the contact hole 30h. The silicon nitride film 33 makes direct contact with the source and drain region 3. It is possible to replace the silicon nitride film 33 with another insulating substance such as a silicon oxide film, of which the material is TEOS (tetra ethyl ortho silicate).

Next, a process for the DRAM as shown in FIG. 2 is described. Referring to FIG. 4, the gate oxide film and the gate electrode (not shown in FIG. 4) are formed on the surface of the silicon substrate 1. By injecting impurity ions into the silicon substrate 1 using the gate electrode as a mask, the source and drain region 3 is formed. The interlayer insulating film 20 made of TEOS as a material is formed so as to cover the surface of the silicon substrate 1. The doped polysilicon film 210 is formed through CVD on the interlayer insulating film 20. A resist is applied to the doped polysilicon film 210 and a resist pattern 310 is formed by patterning this resist in accordance with a photolithographic process. At this time, a protruding part 311 occurs in the resist pattern 310 due to an error, or the like, at the time of transfer.

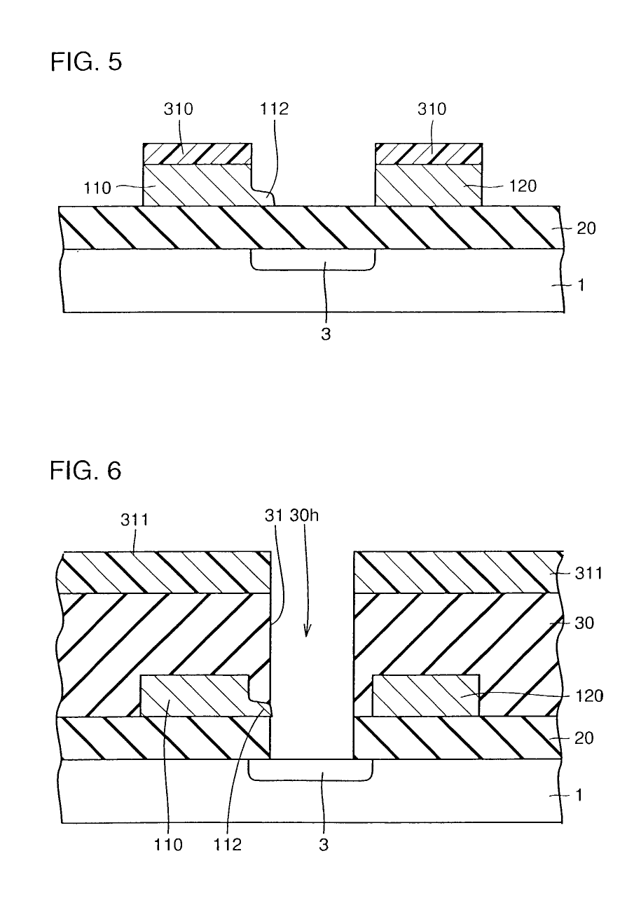

Referring to FIG. 5, the doped polysilicon film 210 is etched by using the resist pattern 310 as a mask. At this time, as the etching progresses the doped polysilicon film 210 is removed and at the initial stage of the etching, the doped polysilicon film beneath the protruding part 311 is not etched because of the existence of the protruding part 311. When the etching has progressed to a certain extent so that the protruding part 311 is etched and removed, the doped polysilicon film 210 beneath the protruding part 311 is also etched. Therefore, at the stage where the etching is finished a small amount of doped polysilicon film remains beneath the protruding part 311 so that this part becomes the protruding part 112 of the bit line 110. Here, the resist pattern 310 above the bit lines 110 and 120 is also etched so that the thickness thereof becomes lesser.

Referring to FIG. 6, the interlayer insulating film 30, made of TEOS as a material, is formed so as to cover the bit lines 110 and 120. The resist pattern 311 is formed on the interlayer insulating film 30. By etching the interlayer insulating films 30 and 20 using the resist pattern 311 as a mask, the contact hole 30h which reaches to the source and drain region 3 is formed in the interlayer insulating film 30 and 20. The contact hole 30h is defined by the sidewalls 31 of the interlayer insulating films 30 and 20. At this time, part of the surface of the protruding part 112 of the bit line 110 is exposed through the contact hole 30h.

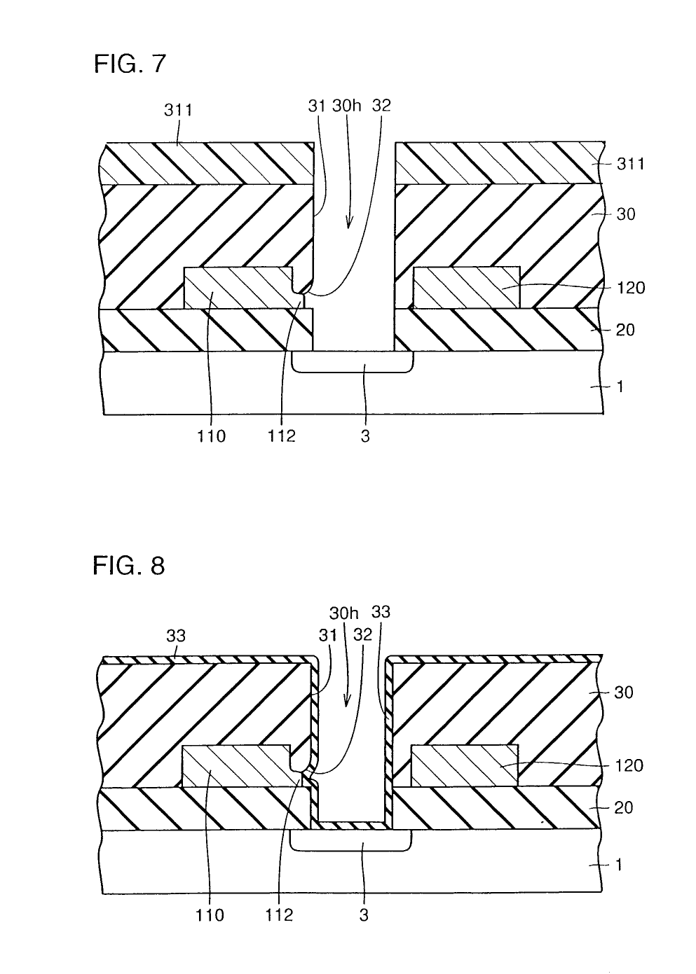

Referring to FIG. 7, part of the surface of the protruding part 112 of the bit line 110, which is exposed through the contact hole 30h, is etched. At this time, since the bit line 110 is formed of a doped polysilicon, wet etching for approximately 5 to 10 minutes is carried out with an ammonium hydroxide (NH₄OH) solution or a mixed solution of hydrogen fluoride (HF) and nitric acid (HNO₃). Here, in the case that the bit line 110 is formed of a metal such as tungsten or aluminum, wet etching for approximately 5 to 10 minutes is carried out with a mixed solution of sulfuric acid (H₂SO₄) and hydrogen peroxide (H₂O₂) or with a mixed solution of hydrochloric acid (HCl) and hydrogen peroxide (H₂O₂). Thereby, a part of the protruding part 112 is removed and the protruding part 112 is removed so that the length of the protruding part 112 becomes shorter. Together with this, the extending part 32 occurs in the part where the protruding part 112 existed as a part of the contact hole 30h. The extending part 32 extends in the direction approaching the bit line 110. This etching is carried out under the condition where the etching rate of the bit line 110 is greater than the etching rates of the silicon substrate 1 and of the silicon oxide film which forms the interlayer insulating films 20 and 30.

Here, though the protruding part 112 is etched by carrying out wet etching in the step shown in FIG. 7, etching in this manner would not etch the bit line 110 in the case that the protruding part 112 has not occurred and, therefore, the introduction of this etching into the process would cause no particular problems.

Referring to FIG. 8, a silicon nitride film 33 is formed through CVD so as to make contact with the sidewalls 31 of the hole 30h. The silicon nitride film 33 covers the surface of the interlayer insulating film 30 and makes contact with the source and drain region 3 formed in the silicon substrate 1. The silicon nitride film 33 extends along the extending part 32 and, in addition, makes contact with the protruding part 112 of the bit line 110.

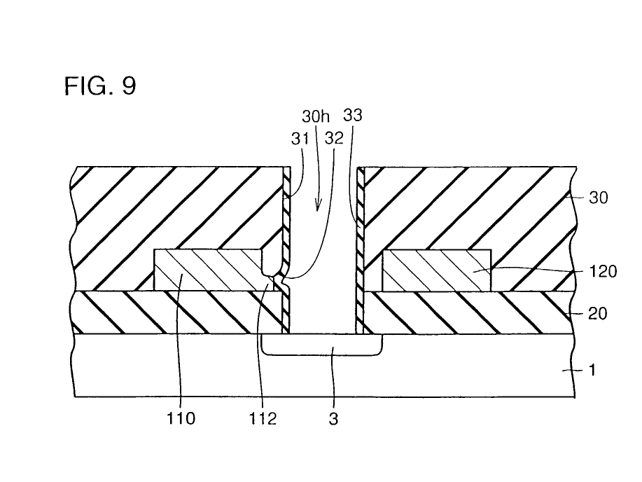

Referring to FIG. 9, the silicon nitride film 33 is etched back on the entire surface. Thereby, the silicon nitride film 33 which makes contact with the top surface of the interlayer insulating film 30 and the silicon nitride film 33 which makes contact with the source and drain region 3 are removed. Therefore, the surface of the source and drain region 3 is exposed.

Referring to FIG. 2, a doped polysilicon film is formed on the interlayer insulating film 30 so as to fill into the contact hole 30h and so as to make contact with the silicon nitride film 33. A resist pattern is formed on the doped polysilicon film and the doped polysilicon film is patterned in accordance with the resist pattern. Thereby, the storage node 140 is formed. A silicon nitride film and a doped polysilicon film are formed on the storage node 140. A resist pattern is formed on the doped polysilicon film and by etching the doped polysilicon film and the silicon nitride film in accordance with this resist pattern, the cell plate 160 and the dielectric film 150 are formed. In this manner, the DRAM 100 as shown in FIG. 2 is completed.

In the DRAM formed in this manner, firstly, the silicon nitride film 33 exists between the storage node 140 and the bit line 110. Thereby, since the bit line 110 and the storage node 140 are insulated from each other, the DRAM 100 does not become a defective product. As a result, the reliability of the DRAM 100 is improved.

In addition, the protruding part 112 of the bit line 110 is partially removed through wet etching in the step shown in FIG. 7. Thereby, even in the case that the protruding part 112 sticks into the contact hole 30h this protruding part can be removed so that the desired diameter of the contact hole 30h can be maintained.

### Second Embodiment

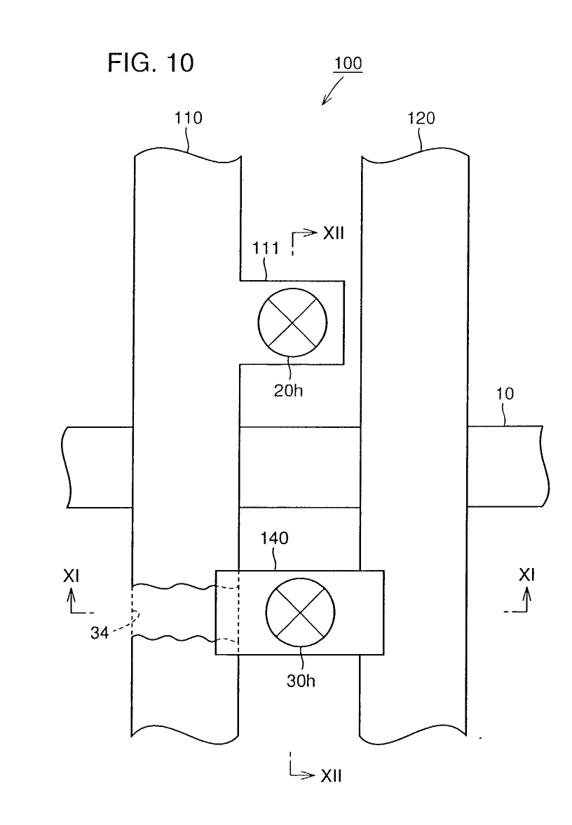

Referring to FIG. 10, a DRAM 100 in accordance with the second embodiment of this invention is different from the DRAM 100 in accordance with the first embodiment in the point that the bit line 110 is divided by the hole 34.

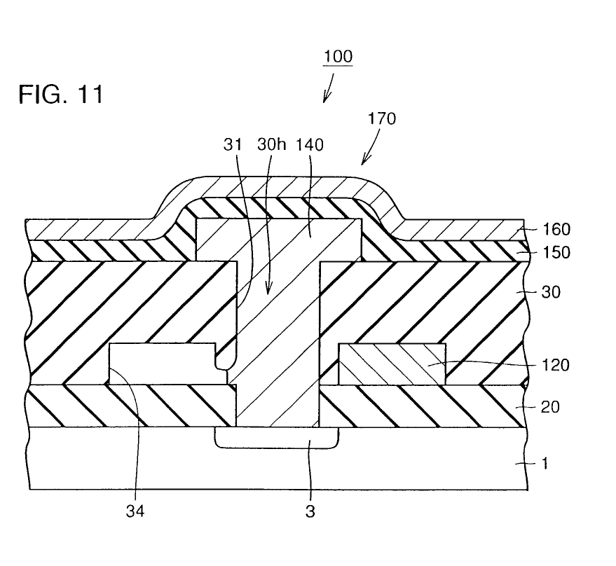

Referring to FIG. 11, the DRAM 100 in accordance with the second embodiment of this invention is different from the DRAM 100 in accordance with the first embodiment in the point that no silicon nitride film is formed on the sidewalls 31 which define the contact hole 30h. In the cross section shown in FIG. 11, no bit line 110 is formed and the DRAM of this embodiment is different from the DRAM in accordance with the first embodiment in the point that a hole 34 is created in the location where the bit line 110 exists in the first embodiment.

That is to say, the DRAM 100, as a semiconductor device in accordance with the second embodiment of this invention includes a source and drain region 3, as the first conductive layer, interlayer insulating films 20 and 30, as the insulating layer having the contact hole 30h which reaches to the surface of the source and drain region 3, and a bit line 110, as the second conductive layer which is covered by the interlayer insulating films 20 and 30. The contact hole 30h is defined by the sidewalls 31 of the interlayer insulating films 20 and 30. A hole 34, as the second hole, is created in the interlayer insulating films 20 and 30 so as to connect to the contact hole 30h and so as to divide the bit line 110. The DRAM 100 includes a storage node 140 which is isolated from the bit line 110 so as to be electrically insulated from the bit line 110 and which fills in the contact hole 30h so as to be electrically connected to the source and drain region 3.

Here, the storage node 140 is isolated from the bit line 110 so as to be electrically insulated from the bit line 110 and fills in the contact hole 30h so as to be electrically connected to the source and drain region 3.

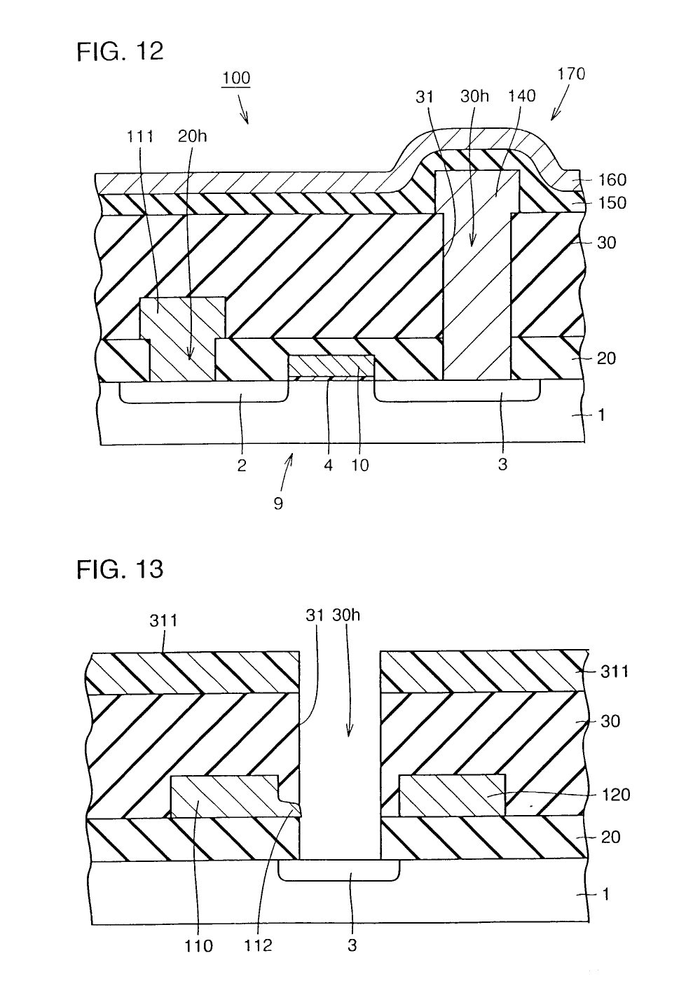

Referring to FIG. 12, the DRAM 100 in accordance with the second embodiment of this invention is different from the DRAM 100 in accordance with the first embodiment in the point that no silicon nitride film is formed on the sidewalls 31 of the contact hole 30h.

First, in the same manner as in the step shown in FIG. 4 of the first embodiment, a gate oxide film and a gate electrode (not shown) are formed on the surface of the silicon substrate 1. By injecting impurity ions into the silicon substrate 1 using the gate electrode as a mask, the source and drain region 3 is formed. An interlayer insulating film 20 made of a silicon oxide film is formed on the surface of the silicon substrate 1. A doped polysilicon film 210 is formed on the interlayer insulating film 20. A resist is applied to the doped polysilicon film 210 and this resist is patterned through a photolithographic process. Thereby, the resist pattern 310 is formed. Here, a protruding part 311 occurs in the resist pattern 310 due to a mismatch at the time of transfer.

In the same manner as in FIG. 5 of the first embodiment, the doped polysilicon film 210 is etched by using the resist pattern 310 as a mask. At this time, as the etching progresses, the doped polysilicon film 210 is removed and, at the initial stage of the etching, the doped polysilicon film beneath the protruding part 311 is not etched because of the existence of the protruding part 311. When the etching progresses to a certain extent so that the protruding part 311 is etched and removed, the doped polysilicon film 210 beneath the protruding part 311 is also etched. Therefore, at the stage where the etching is finished a small amount of doped polysilicon film remains beneath the protruding part 311 so that this part becomes the protruding part 112 of the bit line 110. Here, the resist pattern 310 on the bit lines 110 and 120 is also etched so that the thickness thereof becomes lesser.

Referring to FIG. 13, an interlayer insulating film 30 is formed so as to cover the bit lines 110 and 120. A resist is applied to the interlayer insulating film 30 and a resist pattern 311 is formed by patterning this resist into a predetermined form in accordance with a photolithographic process. By etching the interlayer insulating films 20 and 30 in accordance with the resist pattern 311 the contact hole 30h is formed. The contact hole 30h is defined by the sidewalls 31 of the interlayer insulating films 20 and 30.

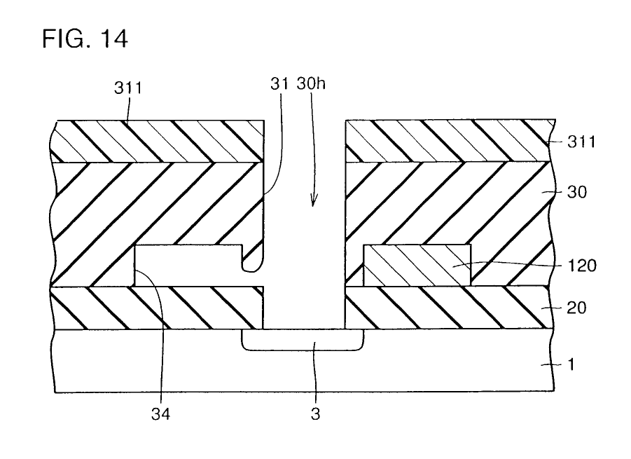

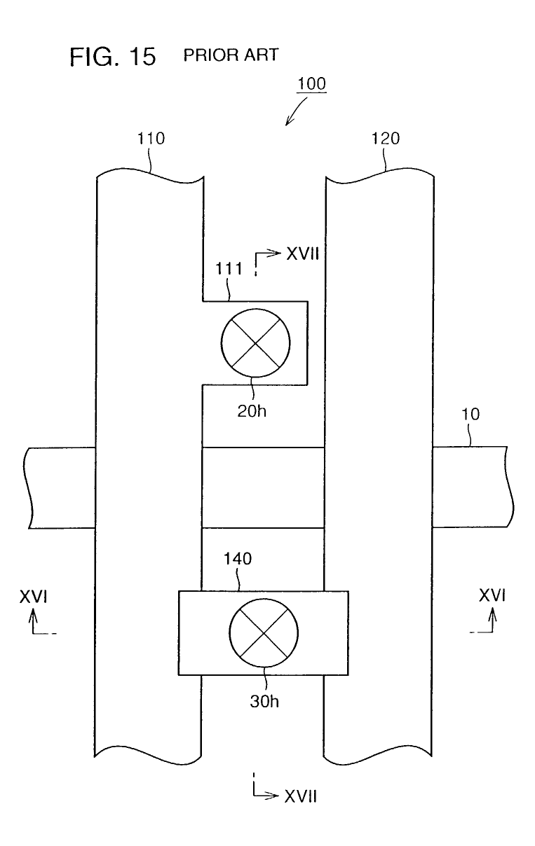

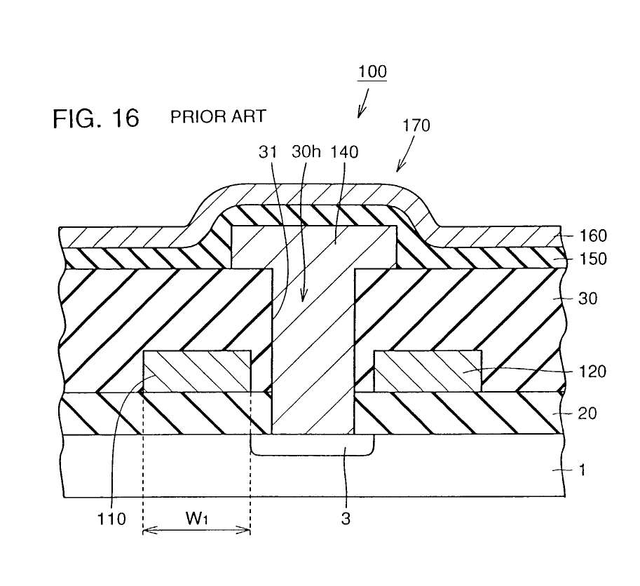

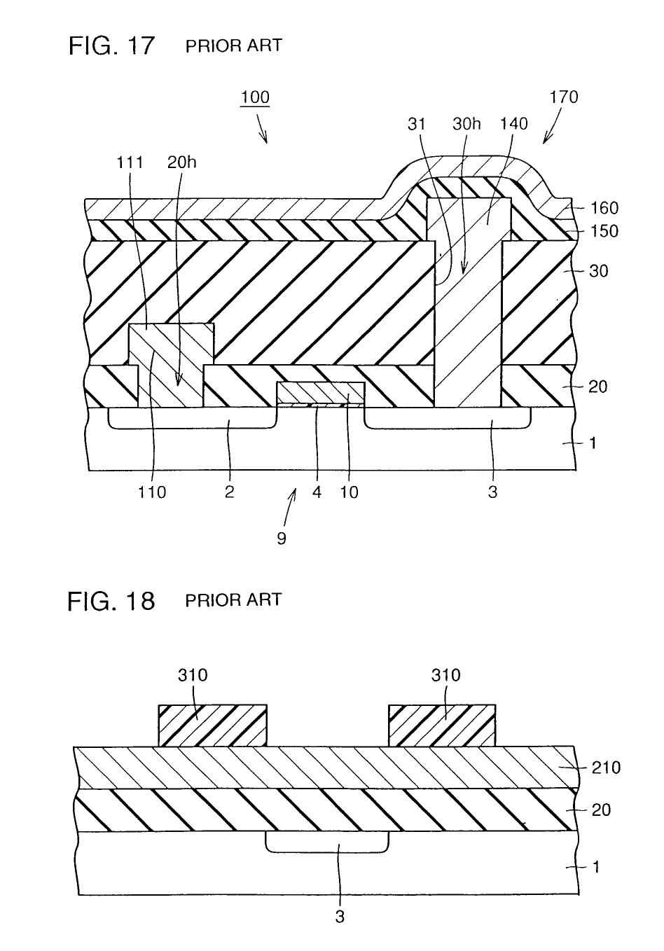

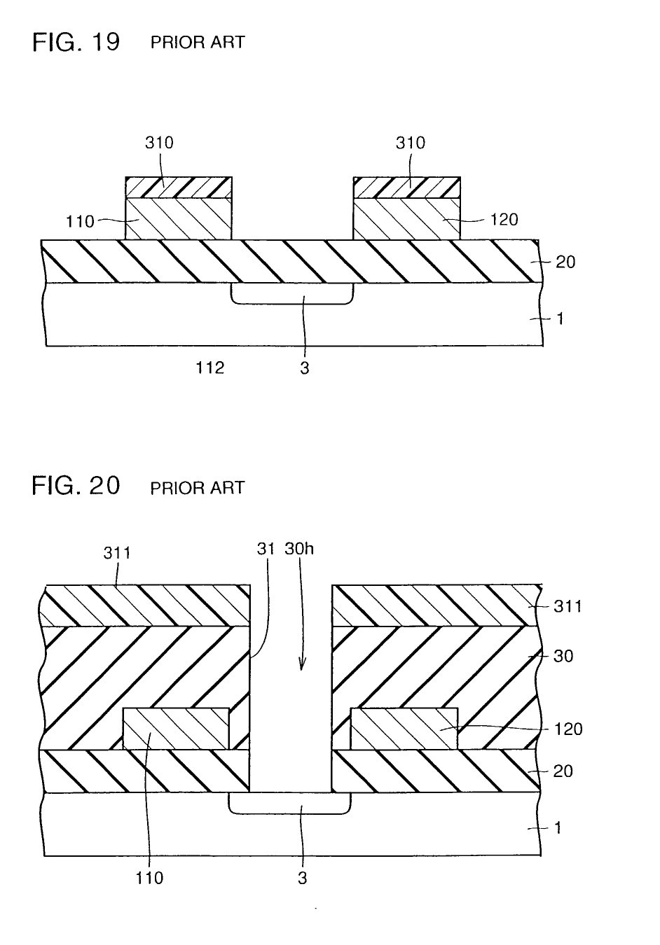

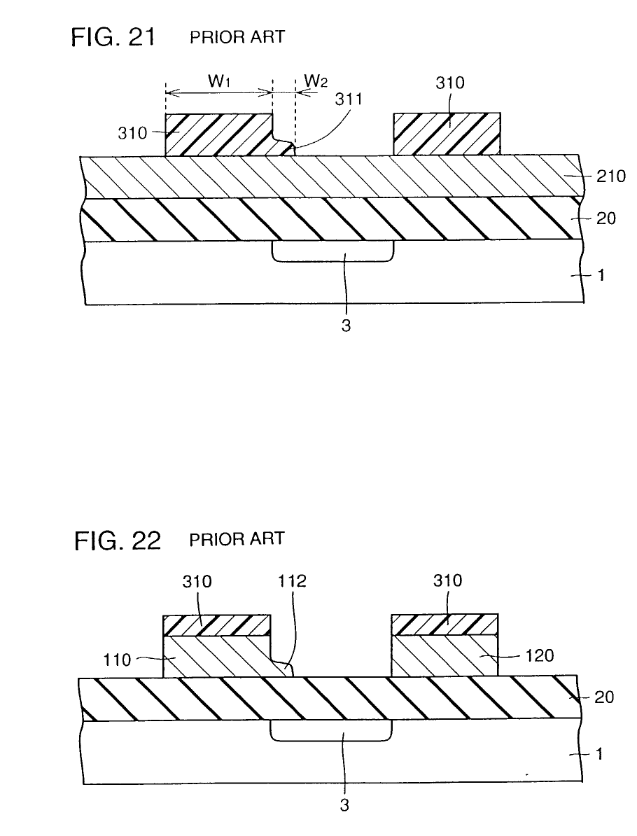

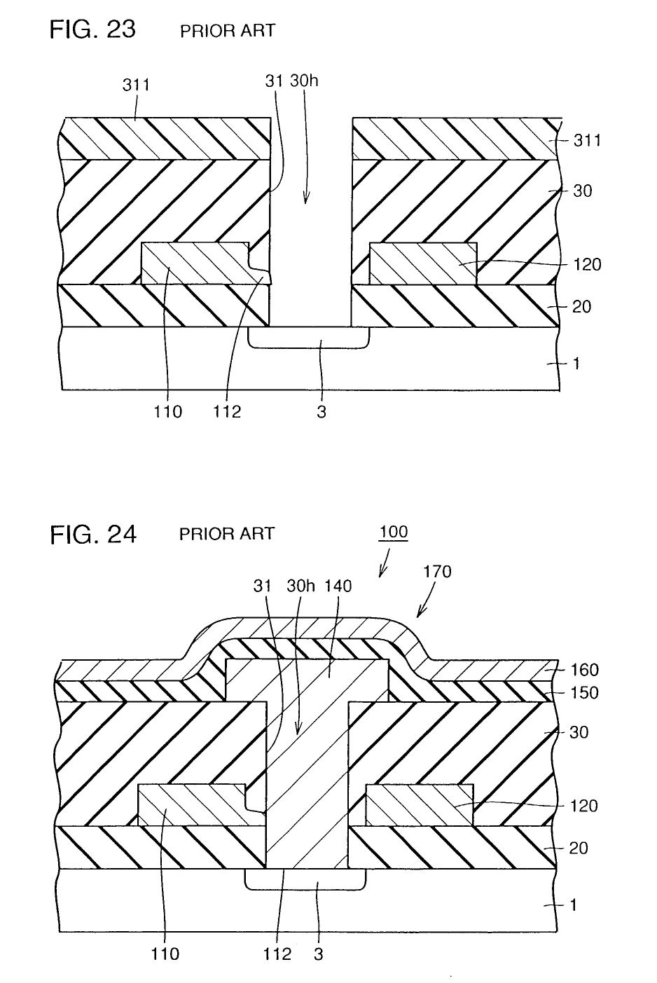

Referring to FIG. 14, wet etching for approximately 10 to 20 minutes is carried out on the bit line 110 in order to divide the bit line 110. At this time, in the case that the bit line 110 has been formed of doped polysilicon, wet etching is carried out with an ammonium hydroxide (NH₄OH) solution or with a mixed solution of hydrogen fluoride (HF) and nitric acid (HNO₃). In addition, in the case that the bit line 110 is formed of a metal such as tungsten or aluminum, the wet etching is carried out with a mixed solution of sulfuric acid (H₂SO₄) and hydrogen peroxide (H₂O₂) or with a mixed solution of hydrochloric acid (HCl) and hydrogen peroxide (H₂O₂). Thereby, the bit line 110 is divided to create a hole 34. The hole 34, which has approximately the same form as the bit line 110, divides the bit line 110 which extends in the direction from the front to the rear of the paper surface. At this time, the bit line 110 is etched under the condition that the etching rate of the bit line 110 is greater than the etching rates of the source and drain region 3 and the interlayer insulating films 20 and 30.

Referring to FIG. 11, a doped polysilicon film is formed on the interlayer insulating film 30 so as to fill in the contact hole 30h. A resist pattern is formed on the interlayer insulating film 30 and a storage node 140 is formed by etching the doped polysilicon film in accordance with this resist pattern. A silicon nitride film and a doped polysilicon film are formed on the storage node 140. A resist pattern is formed on the doped polysilicon film and a cell plate 160 and a dielectric film 150 are formed by etching the doped polysilicon film and the silicon nitride film in accordance with this resist pattern. Thereby, the DRAM 100 is completed.

In such a DRAM 100, as shown in FIGS. 10 and 11, the bit line 110 is divided by the hole 34. When the bit line 110 is divided in this manner it can be detected, with a high probability, in a subsequent step that this bit line 110 is defective. Therefore, defects can be recognized at an early stage so that this bit line can be recognized as defective. Normally, in a DRAM a spare circuit (redundancy circuit) is formed. Thereby, even when a certain bit line is defective, the DRAM as a whole may, by using another bit line, remain a good product. Accordingly, even if the bit line 110 is broken the DRAM 100 as a whole remains a good product and, therefore, a DRAM 100 with a high reliability can be gained.

Though the embodiments of this invention are described above, it is possible to modify the embodiments shown here in a variety of ways. First, as for the materials for forming the bit lines 110 and 120, not only doped polysilicon but also tungsten, aluminum, copper, or the like, can be used. Here, in the case that a metal is used it is necessary to form a barrier layer, or the like, around the wire layer.

In addition, as for the dielectric film 150 of the capacitor 170, though a silicon nitride film is used the invention is not limited to this but, rather, a ferroelectric film such as a tantalum oxide film.

In addition, as for the form of the capacitor 170, a form buried in the silicon substrate 1 or a cylindrical capacitor may be used.

According to this invention a semiconductor device with a high reliability can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a first conductive layer;
a first insulating layer having a hole which reaches to the surface of said first conductive layer; and
a second conductive layer which is covered by said first insulating layer, wherein
said hole is defined by the sidewalls of said first insulating layer and
said semiconductor device further comprises:
a second insulating layer formed on the sidewalls of said hole; and
a third conductive layer which fills in said hole so as to be electrically connected to said first conductive layer.

2. The semiconductor device according to claim 1, wherein part of the surface of said second conductive layer is exposed through said hole in said first insulating layer and is separated from said third conductive layer by said second insulating layer.

3. The semiconductor device according to claim 1, wherein said hole includes an extending part which extends in the direction approaching said second conductive layer.

4. The semiconductor device according to claim 1, wherein:
said first conductive layer is one of a pair of source and drain regions which are formed in a semiconductor substrate so as to be spaced apart from each other;
said second conductive layer is a bit line of a dynamic random access memory which is connected to the other one of said pair of source and drain regions; and
said third conductive layer is a storage node of said dynamic random access memory which is connected to one of said pair of source and drain regions.

5. A semiconductor device comprising:
a first conductive layer;
a first insulating layer having a first hole which reaches to the surface of said first conductive layer; and
a second conductive layer which is covered by said first insulating layer, wherein
said first hole is defined by the sidewalls of said first insulating layer and
a second hole is formed in said first insulating layer so as to continue to said first hole and so as to divide said second conductive layer;
said semiconductor device further comprises a third conductive layer which is isolated from said second conductive layer so as to be electrically insulated from said second conductive layer and which fills in said first hole so as to be electrically connected to said first conductive layer.

6. The semiconductor device according to claim 5, wherein:
said first conductive layer is one of a pair of source and drain regions which are formed in a semiconductor substrate so as to be spaced apart from each other;
said second conductive layer is a bit line of a dynamic random access memory which is connected to the other one of said pair of source and drain regions; and
said third conductive layer is a storage node of said dynamic random access memory which is connected to one of said pair of source and drain regions.

7. A fabrication process for a semiconductor device comprising:
the step of forming a first conductive layer in a semiconductor substrate;
the step of forming a second conductive layer on said semiconductor substrate;
the step of forming a first insulating layer which covers said second conductive layer;
the step of creating a hole, which reaches to the surface of said first conductive layer and which has sidewalls, in said first insulating layer;
the step of forming a second insulating layer on the sidewalls of said hole; and
the step of forming a third conductive layer, which is electrically connected to said first conductive layer and which fills in said hole on said second insulating layer.

8. The fabrication process for a semiconductor device according to claim 7, wherein the step of forming said hole in said first insulating layer includes the formation of a hole which exposes part of the surface of said second conductive layer and the step of forming said second insulating layer on the sidewalls of said hole includes the formation of said second insulating layer which makes contact with said exposed second conductive layer.

9. The fabrication process for a semiconductor device according to claim 8, further comprising the step of removing part of the surface of said second conductive layer which appears in said hole.

10. The fabrication process for a semiconductor device according to claim 9, wherein the step of removing part of the surface of said second conductive layer includes the etching of the second conductive layer under the condition where the etching rate of said second conductive layer is greater than the etching rates of said first conductive layer and of said first and second insulating layers.

11. The fabrication process for a semiconductor device according to claim 9, wherein the step of removing part of the surface of said second conductive layer includes the wet etching of said second conductive layer.

12. A fabrication process for a semiconductor device comprising:
the step of forming a first conductive layer in a semiconductor substrate;
the step of forming a second conductive layer on said semiconductor substrate;
the step of forming an insulating layer which covers said second conductive layer;
the step of forming a first hole having sidewalls, which reaches to the surface of said first conductive layer and which exposes part of the surface of said second conductive layer, in said insulating layer;
the step of forming a second hole, which connects to said first hole and which divides said second conductive layer, in said insulating layer by removing the part of said second conductive layer which connects to said first hole; and
the step of forming a third conductive layer which is isolated from said second conductive layer so as to be electrically insulated from said second conductive layer and which fills in said first hole so as to be electrically connected to said first conductive layer.

13. The fabrication process for a semiconductor device according to claim 12, wherein the removal of the part of said second conductive layer includes the etching of said second conductive layer under the condition where the etching rate of said second conductive layer is greater than the etching rates of said first conductive layer and said insulating layer.

14. The fabrication process for a semiconductor device according to claim 12, wherein the removal of the part of said second conductive layer includes the wet etching of said second conductive layer.
